(19) United States
(12) Patent Application Publication
(10) Pub. No.: US 2017/0103981 A1
(43) Pub. Date: Apr. 13, 2017

(54) METHOD FOR FABRICATING CONTACTS TO NON-PLANAR MOS TRANSISTORS IN SEMICONDUCTOR DEVICE

(71) Applicant: United Microelectronics Corp., Hsin-Chu City (TW)

(72) Inventors: Yu-Hsiang Hung, Tainan City (TW); Ssu-I Fu, Kaohsiung City (TW); Chih-Kai Hsu, Tainan City (TW); Jyh-Shyang Jenq, Pingtung County (TW); Chien-Ting Lin, Hsinchu City (TW)

(21) Appl. No.: 14/880,284

(22) Filed: Oct. 12, 2015

(51) Int. Cl. H01L 27/07; H01L 29/06; H01L 21/283; H01L 21/768; H01L 29/78; H01L 29/66

(52) U.S. Cl. CPC H01L 27/0738; H01L 29/785; H01L 29/66795; H01L 21/283; H01L 21/76897; H01L 29/0649; H01L 2029/7858

(57) ABSTRACT

A method for fabricating semiconductor device is disclosed. The method includes the steps of: providing a substrate having a first fin-shaped structure on a first region and a second fin-shaped structure on a second region; forming a plurality of first gate structures on the first fin-shaped structure, a plurality of second gate structures on the second fin-shaped structure, and an interlayer dielectric (ILD) layer around the first gate structures and the second gate structures; forming a patterned mask on the ILD layer; and using the patterned mask to remove all of the ILD layer from the first region and part of the ILD layer from the second region for forming a plurality of first contact holes in the first region and a plurality of second contact holes in the second region.

### BACKGROUND OF THE INVENTION

1. Field of the Invention

The invention relates to a method for fabricating semiconductor device, and more particularly, to a method of integrating gate structures of different pitches and a resistor on a substrate.

2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However, the approach of using etching process to remove the hard mask from gate structure on the edge of fin-shaped structure in current FinFET process and also forming contact holes typically results in uneven openings affecting the formation of contact plugs thereafter and the performance of the device. Hence, how to improve the current process to resolve this issue has become an important task in this field.

### SUMMARY OF THE INVENTION

According to a preferred embodiment of the present invention, a method for fabricating semiconductor device is disclosed. The method includes the steps of: providing a substrate having a first fin-shaped structure on a first region and a second fin-shaped structure on a second region; forming a plurality of first gate structures on the first fin-shaped structure, a plurality of second gate structures on the second fin-shaped structure, and an interlayer dielectric (ILD) layer around the first gate structures and the second gate structures; forming a patterned mask on the ILD layer; and using the patterned mask to remove all of the ILD layer from the first region and part of the ILD layer from the second region for forming a plurality of first contact holes in the first region and a plurality of second contact holes in the second region.

According to another aspect of the present invention, a semiconductor device is disclosed. The semiconductor device includes: a substrate; a resistor on the substrate; a first stop layer on the resistor; a first dielectric layer on the first stop layer; a second stop layer on the first dielectric layer; a second dielectric layer on the second stop layer; and a contact plug in the first stop layer, the first dielectric layer, the second stop layer, and the second dielectric layer and contacting the resistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating semiconductor device according to a preferred embodiment of the present invention.

### DETAILED DESCRIPTION

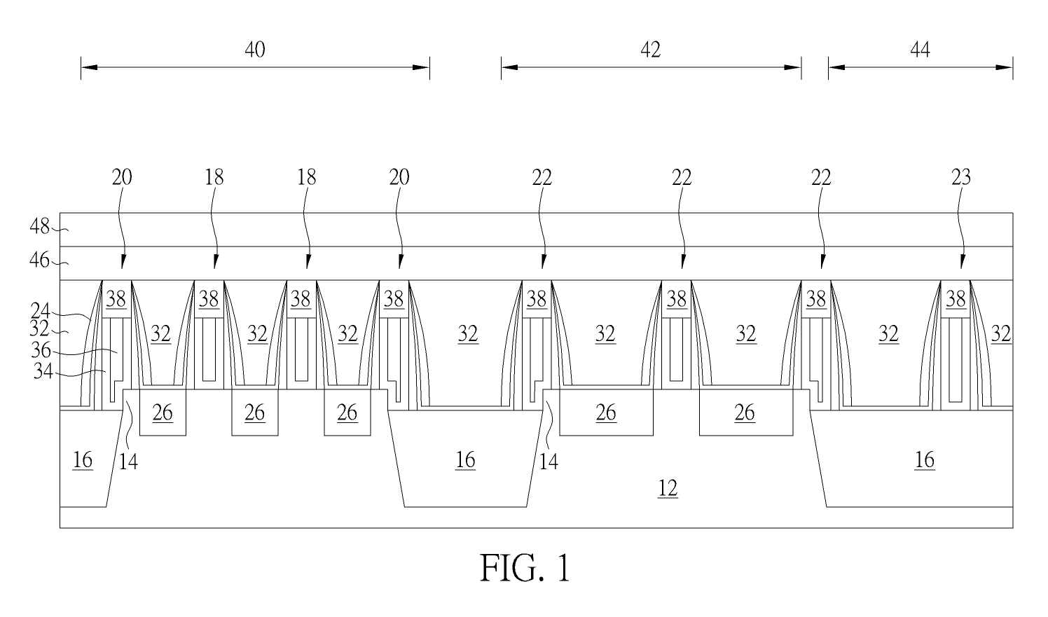

Referring to FIGS. 1-9, FIGS. 1-9 illustrate a method for fabricating semiconductor device according to a preferred embodiment of the present invention. It should be noted despite this embodiment pertains to a non-planar MOS transistor, the method of the present invention could be applied to either planar or non-planar transistor devices depending on the demand of the product. As shown in FIG. 1, a substrate 12, such as a silicon substrate or silicon-on-insulator (SOI) substrate is provided and a first region 40, a second region 42, and a third region 44 are defined on the substrate 12 . Preferably, the first region 40 is used for fabricating gate structures with smaller gaps or pitches in the later process, the second region 42 is used for fabricating gate structures with larger gaps or pitches, and the third region 44 is used for fabricating a resistor afterwards . A fin-shaped structure 14 is then formed on the substrate 12 of the first region 40 and another fin-shaped structure 14 is formed on the substrate 12 of the second region 42, in which the bottom of the fin-shaped structures 14 is enclosed by a shallow trench isolation (STI) 16 preferably composed of an insulating layer such as silicon oxide. Next, a plurality of gate structures 18 and 20 are formed on the fin-shaped structure 14 on first region 40, a plurality of gate structures 22 are formed on the fin-shaped structures 14 on second region 42, and at least a gate structure 23 is formed on the third region 44, in which the gate structures 20 on first region 40 are disposed on the edges of the fin-shaped structure 14 while sitting on the fin-shaped structure 14 and the STI 16 at the same time.

The formation of the fin-shaped structures 14 could be accomplished by first forming a patterned mask (now shown) on the substrate, 12, and an etching process is performed to transfer the pattern of the patterned mask to the substrate 12. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form a STI 16 surrounding the bottom of the fin-shaped structures 14. Alternatively, the formation of the fin-shaped structures 14 could also be accomplished by first forming a patterned hard mask (not shown) on the substrate 12, and then performing an epitaxial process on the exposed substrate 12 through the patterned hard mask to grow a semiconductor layer. This semiconductor layer could then be used as the corresponding fin-shaped structures 14. Similarly, the patterned hard mask could be removed selectively or retained, and deposition, CMP, and then etching back could be used to form a STI 16 surrounding the bottom of the fin-shaped structures 14. Moreover, if the substrate 12 were a SOI substrate, a patterned mask could be used to etch a semiconductor layer on the substrate until reaching a bottom oxide layer underneath the semiconductor layer to form the corresponding fin-shaped structures 14. If this means were chosen the aforementioned steps for fabricating the STI 16 could be eliminated.

The fabrication of the gate structures 18, 20, 22, 23 could be accomplished by a gate first process, a high-k first approach from gate last process, or a high-k last approach from gate last process. Since this embodiment pertains to a high-k first approach, dummy gates (not shown) composed of high-k dielectric layer and polysilicon material could be first formed on the fin-shaped structures 14 and the STI 16, and a spacer 24 is formed on the sidewall of each dummy gate. A source/drain region 26 and epitaxial layer (not shown) are then formed in the fin-shaped structures 14 and/or substrate 12 adjacent to two sides of the spacer 24, a selective contact etch stop layer (CESL) (not shown) is formed on the dummy gates, and an interlayer dielectric (ILD) layer 32 composed of tetraethyl orthosilicate (TEOS) is formed on the CESL. In this embodiment, the spacer 24 is preferably a composite spacer composed of oxide-nitride-oxide, but not limited thereto.

Next, a replacement metal gate (RMG) process could be conducted to planarize part of the ILD layer 32 and then transforming the dummy gate into metal gates 18, 20, 22, and 23. The RMG process could be accomplished by first performing a selective dry etching or wet etching process, such as using etchants including ammonium hydroxide (NH₄OH) or tetramethylammonium hydroxide (TMAH) to remove the polysilicon material from dummy gates for forming recesses (not shown) in the ILD layer 32. Next, a conductive layer including at least a U-shaped work function metal layer 34 and a low resistance metal layer 36 is formed in the recesses, and a planarizing process is conducted thereafter so that the surface of the U-shaped work function metal layer 34 and low resistance metal layer 36 is even with the surface of the ILD layer 32.

In this embodiment, the work function metal layer 34 is formed for tuning the work function of the later formed metal gates to be appropriate in an NMOS or a PMOS. For an NMOS transistor, the work function metal layer 34 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 34 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 34 and the low resistance metal layer 36, in which the material of the barrier layer may include titanium (Ti), titanium nitride (TiN), tantalum (Ta) or tantalum nitride (TaN). Furthermore, the material of the low-resistance metal layer 36 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

Next, part of the work function metal layer 34 and low resistance metal layer 36 could be removed, and hard masks 38 are formed on the work function metal layer 34 and the low resistance metal layer 36 to form the gate structures 18, 20, 22, and 23. Each of the hard masks 38 could be a single material layer or composite material layer, such as a composite layer containing both silicon oxide and silicon nitride.

Next, a cap layer 46 is covered entirely on the gate structures 18, 20, 22, 23 and the ILD layer 32 and a mask layer 48 is formed on the cap layer 46 thereafter. In this embodiment, the cap layer 46 is preferably used as a pre-metal dielectric (PMD) layer, in which the cap layer 46 and the ILD layer 32 could be composed of same material or different material. The cap layer 46 is preferably composed of material such as silicon oxide. The mask layer 48 is preferably a metal mask composed of TiN.

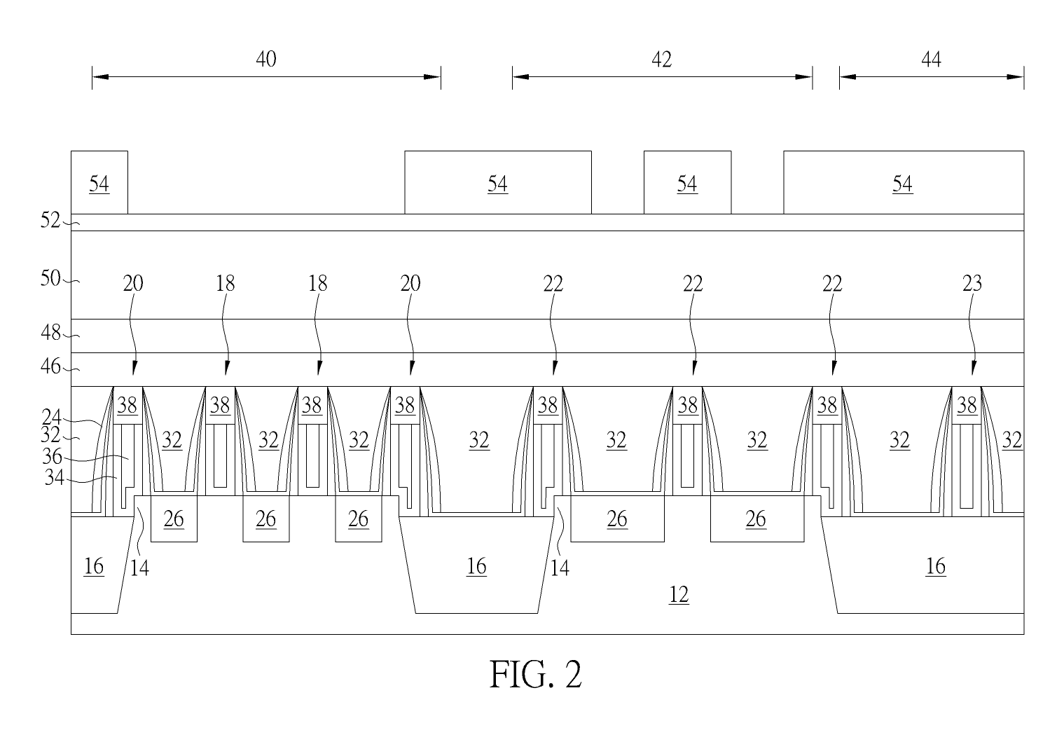

Next, as shown in FIG. 2, an organic dielectric layer (ODL) 50, a silicon-containing hard mask bottom anti-reflective coating (SHB) 52, and a patterned mask 54 are formed on the mask layer 48, in which the patterned mask 54 could be a patterned resist or a patterned mask composed of TiN.

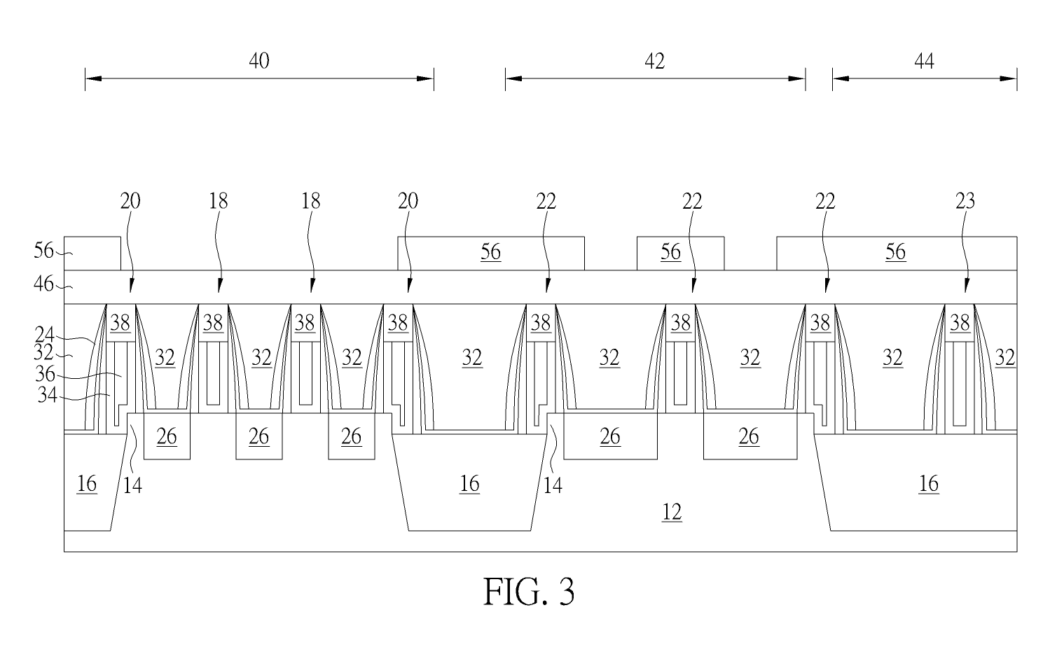

Next, as shown in FIG. 3, an etching process is conducted by using the patterned mask 54 as mask to remove part of the SHB 52, part of the ODL 50, and part of the mask layer 48, and the patterned mask 54, remaining SHB 52, and remaining ODL 50 are then removed to form a patterned mask 56 on the cap layer 46.

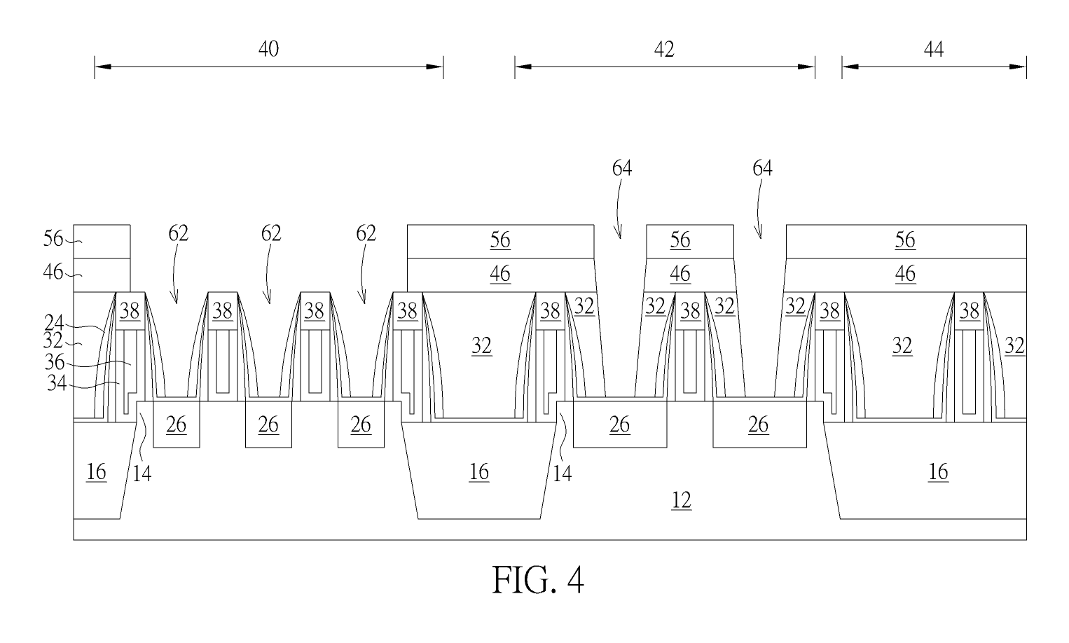

Next, as shown in FIG. 4, an etching process is conducted by using the patterned mask 56 to remove part of the cap layer 46, and part of the ILD layer 32 not covered by the patterned mask 56 for forming a plurality of contact holes 62 and 64. It should be noted that since the patterned mask 56 covers all of the third region 44 and part of the second region 42 but expose all of the first region 40, all of the ILD layer 32 on first region 40 is preferably removed by etching process to form contact holes 62 while only part of the ILD layer 32 on second region 42 is removed by etching process to form contact holes 64 in the ILD layer 32 of second region 42. As a result, no ILD layer 32 is left between the gate structures 18 and 20 on first region 40 while some ILD layer 32 is left between the gate structures 22 on second region 42 and the ILD layer 32 is kept intact on the third region 44.

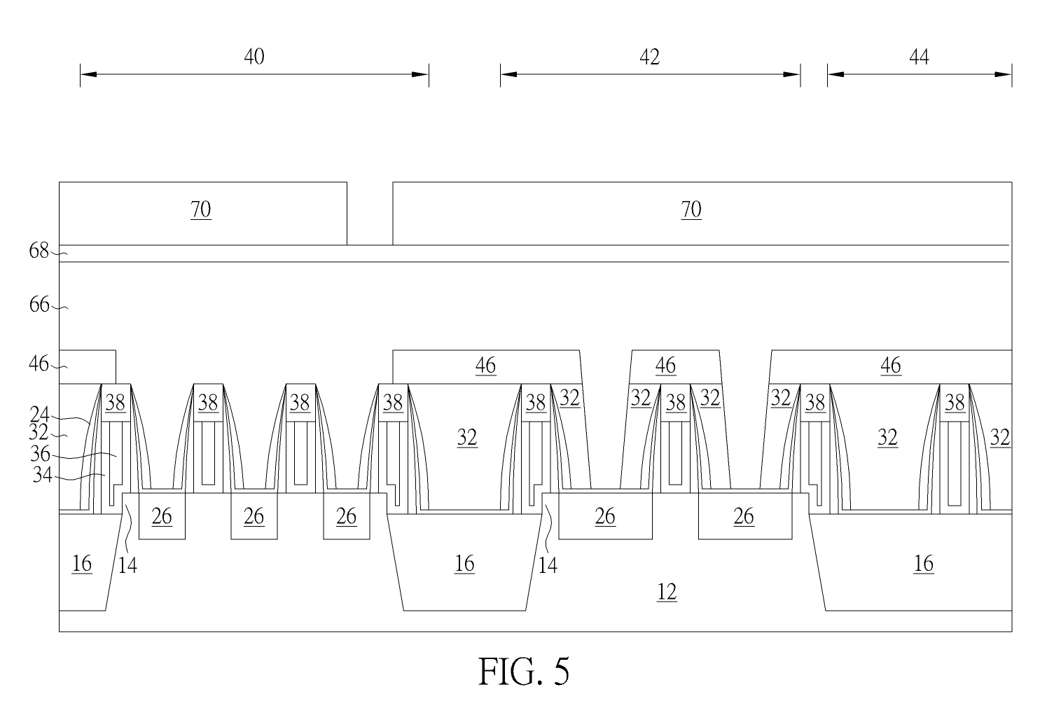

Next, as shown in FIG. 5, after removing the patterned mask 56 completely, another ODL 66, another SHB 68, and another patterned mask 70 are formed on the gate structures 18, 20, 22, 23, ILD layer 32, and cap layer 46 and filled into the contact holes 62 and 64, in which the patterned mask 70 could be a patterned resist or a patterned mask composed of TiN.

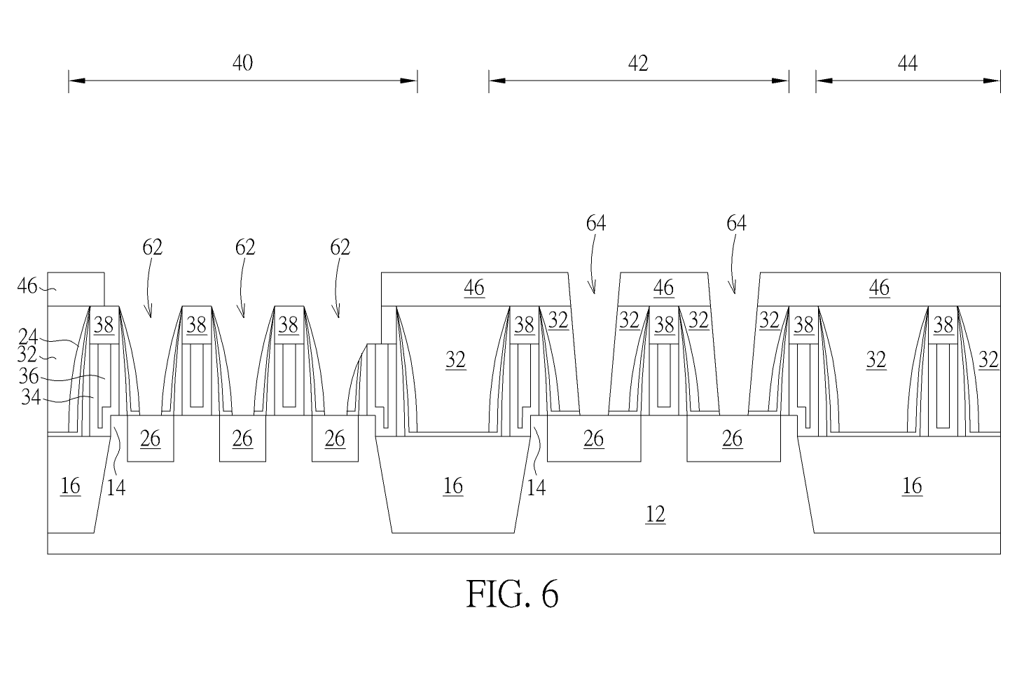

Next, as shown in FIG. 6, an etching process is conducted by using the patterned mask 70 as mask to remove part of the SHB 68, part of the ODL 66, and part of the gate structure 20 on the right edge of fin-shaped structure 14 not covered by the patterned mask 70 on the first region 40 for exposing the electrode surface of the gate structure 20, such as the work function metal layer 34 and low resistance metal layer 36 of gate structure 20. The patterned mask 70, remaining SHB 68, and remaining ODL 66 are removed thereafter.

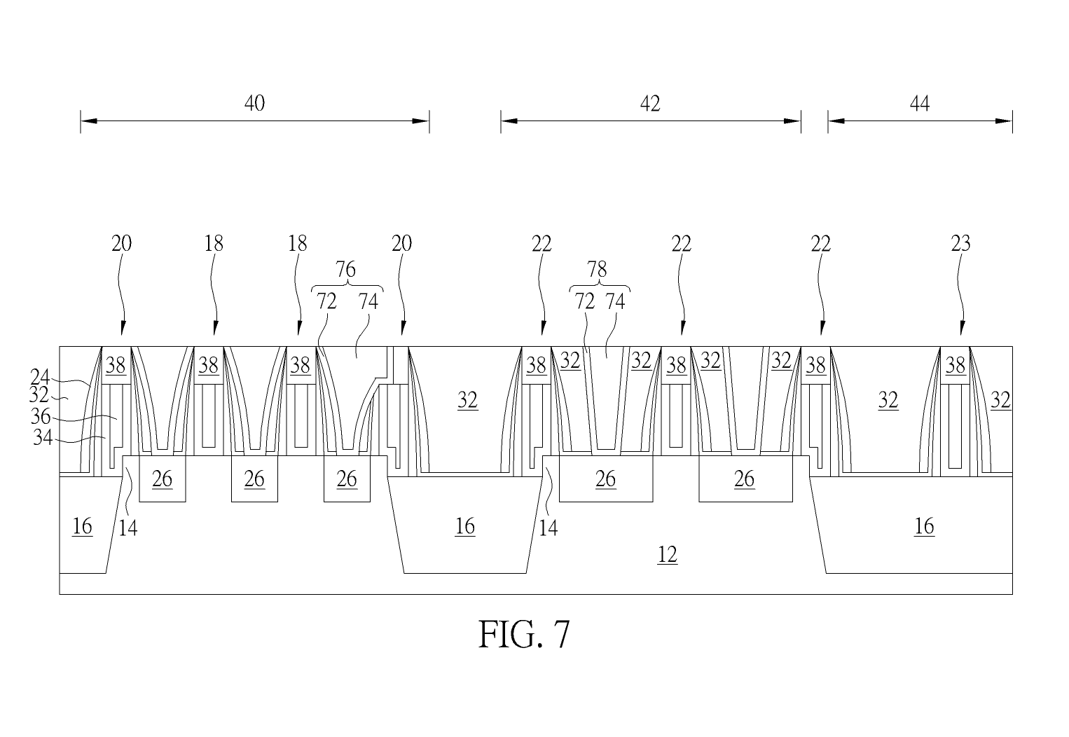

Next, as shown in FIG. 7, a contact plug formation process is conducted by first depositing a barrier layer 72 and a metal layer 74 composed of low resistance material on the gate structures 18, 20, 22, 23, ILD layer 32, and cap layer 46 while filling the contact holes 62 and 64 on first region 40 and second region 42. Next, a CMP process is conducted by using the hard mask 38 as stop layer to remove part of the metal layer 74, part of the barrier layer 72, and cap layer 46 to form a plurality of contact plugs 76 and 78 on the first region 40 and second region 42. In this embodiment, the barrier layer 72 could be selected from the group consisting of Ti, TiN, Ta, and TaN, and the metal layer 74 could be selected from the group consisting of W, Cu, Al, TiAl, and CoWP.

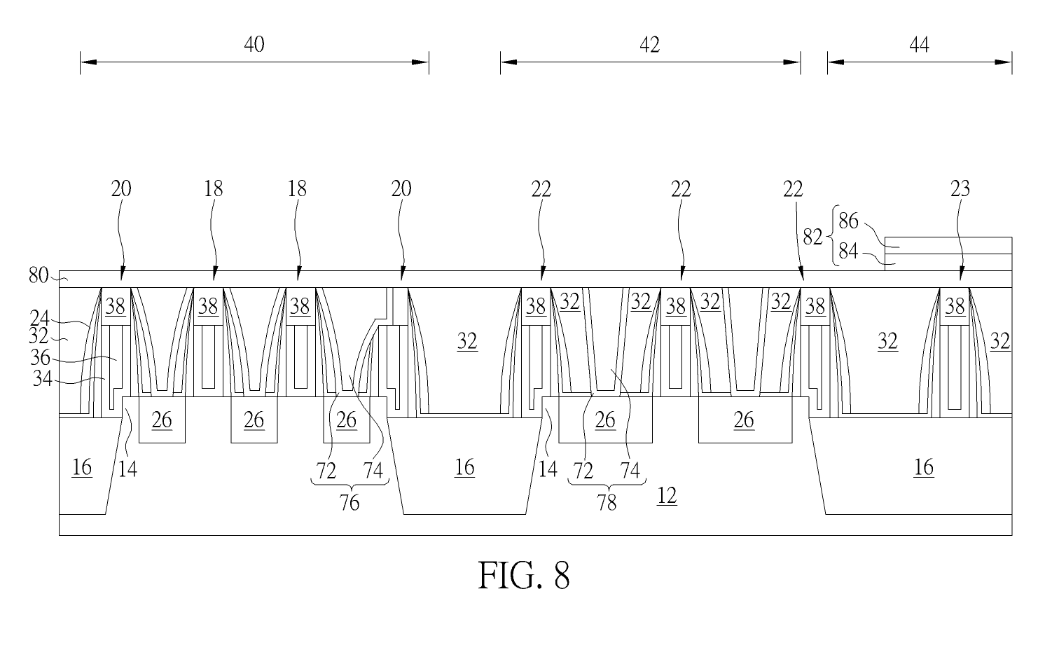

Next, as shown in FIG. 8, an oxide layer 80 is formed on the first region 42, second region 44, and third region 46 to cover the gate structures 18, 20, 22, 23 and contact plugs 76 and 78, and a resistor 82 is formed on the oxide layer 80 of the third region 44. The formation of the resistor could be accomplished by sequentially depositing a first insulating layer (not shown) , a conductive layer (not shown), and a second insulating layer (not shown) on the oxide layer 80, and then conducting a photo-etching process to remove part of the second insulating layer, part of the conductive layer, and part of the first insulating layer outside the third region 44 for forming a resistor 82. It should be noted that since all of the second insulating layer is preferably consumed during the photo-etching process, the resistor 82 is composed of a conductive layer 84 and an insulating layer 86. In this embodiment, the conductive layer 84 preferably includes TiN and the insulating layer 86 includes SiN, but not limited thereto.

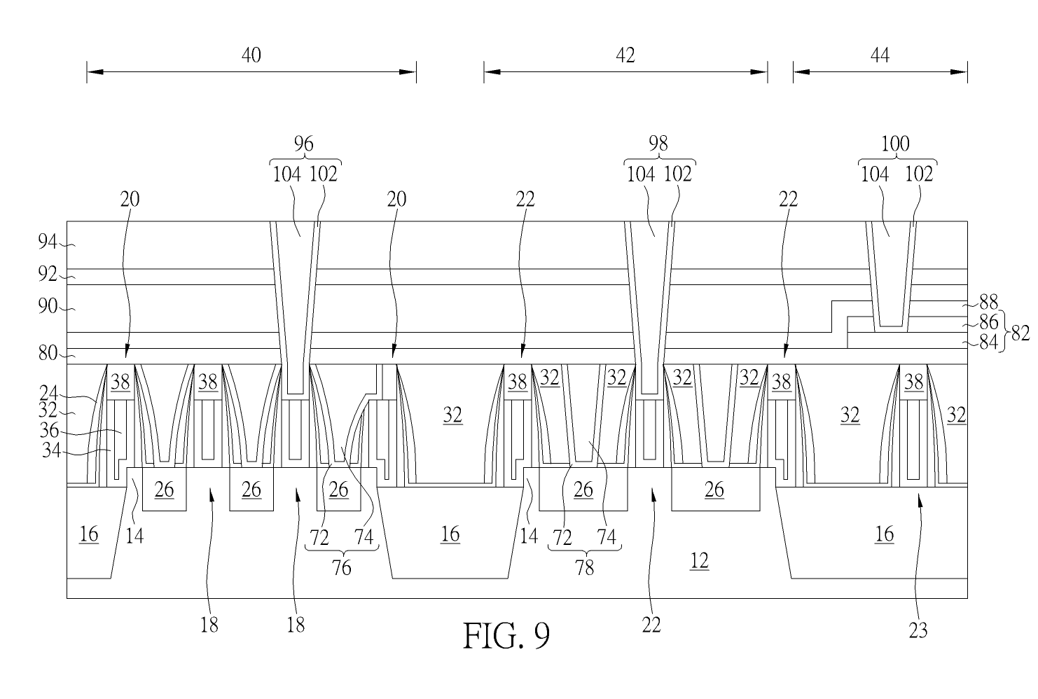

Next, as shown in FIG. 9, a stop layer 88, a dielectric layer 90, a stop layer 92, and another dielectric layer 94 are formed on the oxide layer 80 and the resistor 82, and a contact formation process is conducted to form contact plugs 96, 98, 100, in which each of the contact plugs 96, 98, 100 is composed of a U-shaped barrier layer 102 and a metal layer 104.

Referring to FIG. 9, which further illustrates a structural view of a semiconductor device according to a preferred embodiment of the present invention. As shown in FIG. 9, the semiconductor device includes a plurality of gate structures 18 and 20 on the first region 40, a plurality of gate structures 22 on the second region 44, a gate structure 23 on the third region 44, an oxide layer 80 on the gate structures 18, 20, 22, 23, a resistor 82 on the third region 44, a stop layer 88 on the resistor 82 and the oxide layer 80, a dielectric layer 90 on the stop layer 88, another stop layer 92 on the dielectric layer 90, another dielectric layer 94 on the stop layer 92, and contact plugs 96, 98, 100 in the stop layer 88, dielectric layer 90, stop layer 92, and dielectric layer 94 and contacting the gate structures 18, 22 and the resistor 82.

Preferably, the resistor 82 is composed of a conductive layer 84 and an insulating layer 86, in which the conductive layer 84 is a TiN layer and the insulating layer 86 is a SiN layer, but not limited thereto.

It should be noted that in contrast to the contact plug formed by conventional dual damascene process having trench conductor and via conductor, the contact plugs 96, 98, 100 of the present invention are not fabricated by dual damascene processes, hence each of the contact plugs 96, 98, 100 only contains one single conductor, such as either a trench conductor or a via conductor from typical dual damascene structure. In addition, each of the contact plugs 96, 98, 100 of the aforementioned embodiments preferably includes a U-shaped barrier layer 102 and a metal layer 104 formed atop, in which the top surfaces of the U-shaped barrier layers 102, the metal layers 104, and the dielectric layer 94 are coplanar. Similar to the structure of aforementioned contact plugs 76 and 78, the barrier layer 102 could be selected from the group consisting of Ti, TiN, Ta, and TaN, and the metal layer 104 could be selected from the group consisting of W, Cu, Al, TiAl, and CoWP

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate having a first fin-shaped structure on a first region and a second fin-shaped structure on a second region;
forming a plurality of first gate structures on the first fin-shaped structure, a plurality of second gate structures on the second fin-shaped structure, hard masks on the first gate structures and the second gate structures, and an interlayer dielectric (ILD) layer around the first gate structures and the second gate structures;
forming a mask layer on the ILD layer;
forming a patterned resist on the mask layer;
using the patterned resist to remove part of the mask layer for forming a patterned mask on the ILD layer;
using the patterned mask to remove all of the ILD layer from the first region for exposing the hard masks on the first region and remove part of the ILD layer from the second region for forming a plurality of first contact holes in the first region and a plurality of second contact holes in the second region; and
removing part of the hard masks on the first gate structures.

2. The method of claim 1, further comprising removing the patterned mask after forming the first contact holes and the second contact holes.

3. The method of claim 1, wherein the patterned mask comprises TiN.

4. The method of claim 1, further comprising forming a cap layer on the first gate structures, the second gate structures, and the ILD layer before forming the patterned mask.

5. The method of claim 4, further comprising using the patterned mask to remove part of the cap layer before removing all of the ILD layer from the first region and part of the ILD layer from the second region.

6. The method of claim 4, further comprising:
forming a metal layer in the first contact holes and the second contact holes and on the cap layer and the ILD layer; and
removing part of the metal layer and the cap layer for forming a plurality of first contact plugs in the first region and a plurality of second contact plugs in the second region.

7. A semiconductor device, comprising:
a substrate;
a resistor on the substrate;
a first stop layer on the resistor;
a first dielectric layer on the first stop layer;
a second stop layer on the first dielectric layer;
a second dielectric layer on the second stop layer; and
a contact plug in the first stop layer, the first dielectric layer, the second stop layer, and the second dielectric layer and contacting the resistor, wherein a top surface of the contact plug is even with a top surface of the second dielectric layer, a top surface of the contact plug overlaps a bottom surface of the contact plug, and a sidewall of the contact plug extending from a top surface of the resistor to a top surface of the second dielectric layer comprises an inclined and planar surface.

8. The semiconductor device of claim 7, further comprising:
a fin-shaped structure on the substrate;
a shallow trench isolation (STI) around the fin-shaped structure;
a gate structure on the STI;
an interlayer dielectric (ILD) layer around the gate structure; and
the resistor on the ILD layer and the gate structure.

9. The semiconductor device of claim 7, wherein the resistor comprises:
a TiN layer; and
a SiN layer on the TiN layer.
